(19) United States
(12) Patent Application Publication
(10) Pub. No.: US 2008/0074034 A1
(43) Pub. Date: Mar. 27, 2008

(54) Organic Light Emitting Diode Device and Light Emitting Layer Manufacture Method Thereof

(76) Inventor: Jwo-Huei Jou, Hsinchu (TW)

Correspondence Address: LAW OFFICES OF LAI AND ASSOCIATES, P.C., 5800 RANCHESTER STE 200, HOUSTON, TX, 77036, US

(21) Appl. No.: 11/534,568

(22) Filed: Sep. 22, 2006

(51) Int. Cl. H01L 51/54; H01L 51/56

(52) U.S. Cl. 313/504; 313/506; 428/690; 428/917; 252/301.16; 427/66; 427/69

(57) ABSTRACT

An organic light emitting diode apparatus and light emitting layer manufacture method thereof are disclosed. The manufacture method for manufacturing the light emitting layer of the OLED comprises the following steps: an acetone or a tetrahydrofuran as an organic solvent is provided to dissolve each luminescent material and each host material respectively. The solution of the luminescent material and the solution of the host material are mixed based on a predetermined material concentration to produce a mixed solution. The mixed solution is then dried by a drying procedure to produce a solid mixed material. Lastly, the solid mixed material is fabricated by vapor deposition to make a light emitting layer.

### FIELD OF THE INVENTION

The present invention relates to an organic light emitting diode device and light emitting layer manufacture method thereof and, more particularly, to use organic solvents for manufacturing a light emitting layer of the organic light emitting diode device.

### BACKGROUND OF THE INVENTION

In the early stages, an organic light emitting diode (OLED) is made by vacuum evaporation. Hole-transporting materials and electron transporting materials are coated on indium tin oxide (ITO) glass. Subsequently, a metal electrode is evaporated to form an OLED device with high response speed, light weight, thin thickness, low power consumption, high brightness, full-color and wide view angle. Hence, the OLED device can be applied into a full-color display or can emit the white light to achieve the goals of power saving and environmental protection. Referring to FIG. 1, a cross-sectional drawing illustrates a conventional OLED device. The structure of the OLED device sequentially includes a transparent substrate 11, an Indium Tin Oxide (ITO) positive electrode 12, a hole-transporting layer 13, an organic emitting layer 14, an electron transporting layer 15, an electron injection layer 16 and a metal negative electrode 17. The positive electrode 12, the hole-transporting layer 13, the organic emitting layer 14, the electron transporting layer 15, the electron injection layer 16 and the negative electrode 17 are formed through a vapor deposition as evaporation. When a forward bias is imposed, holes 131 inject from the positive electrode 12 and electrons 151 inject from the negative electrode 17. The holes 131 and the electrons 151 move in a thin film due to potential differences caused by external electric fields. A recombination is then generated in the organic emitting layer 14. Some energy released by the electrons combined with the holes emits luminescent molecules of the organic emitting layer 14 to become excited states. When the luminescent molecules disintegrate to ground states from the excited states, a proportion of energy is released by using photonic shapes. The emitted light is organic electroluminescence.

The color light emitted by the OLED depends on organic materials with luminescence characters in elements, or is obtained by doping organic luminescent materials into a host material. A vacuum evaporation is used to dope a micro-luminescent material and a micro-luminescent material into the host material respectively to allow the materials to emit a red light and a green light. The color light is also controlled to become an orange from the red through the proportion of dopants.

The color character of the light emitted by the OLED is defined by color coordinates x and y from Commission International de L'Eclairage (CIE). Referring to FIG. 2, a schematic diagram illustrates a color coordinate showed by a two-dimensional pattern of the CIE coordinate. A horseshoe curve 21 is a range of the color coordinate, which means the CIE color coordinate and a spectrum shape of the light with certain energy will be in the range of the curve. The positions of monochromatic light are a blue light at lower left, a red light at lower right and a green light at upper respectively. A white light or an intermediate point (the CIE color coordinates x and y are 0.33, 0.33) is obtained from the horseshoe curve 21 when the averages of all wavelengths are summed up. In addition, there is a generalized white light color range 22. If the color coordinate of the color light is in the range 22, the white light is defined. The CIE color coordinate x of the generalized white light color range is between 0.25 and 0.45. The CIE color coordinate y is between 0.25 and 0.45. An ellipse area is therefore formed on the diagram. General speaking, when the white light is used for illumination, the color rendering index of the white light needs to be at least 70.

White light is a combination of visible lights. It is unlike monochrome light with a specific wavelength or a range. White light is formed by mixing with red, green and blue lights. White light is also formed by mixing with yellow and blue lights, or is mixed with other color lights. These color lights can be dispersed in a light emitting structure with multiple layers to emit lights respectively. Alternatively, these color lights can be concentrated into a single layer structure for emitting lights. Therefore, the organic emitting layer of the white light OLED can be divided into multiple layers or a single layer. The white light OLED of the light emitting structure with multiple layers is composed of three layers from red, green and blue lights in prior arts. In addition, an organic emitting layer of the white light device is composed of a blue light emitting layer and an electron transporting layer or a hole-transporting layer doped with a yellow material in prior arts. In addition, the white light OLED device is composed of a blue light emitting layer and the hole-transporting layer doped with a red luminescent material and a green luminescent material in prior arts. The white light OLED of the light emitting structure with single layer is that the white light emitting layer is composed of doping citrus red light and blue luminescent material or a red luminescent material, a green luminescent material and a blue luminescent material into the host material simultaneously by using vacuum evaporation in prior arts.

In the foregoing conventional techniques, the color can be modified and the luminescence efficiency can be improved by selecting the proportion of doping luminescent materials. However, the doping of the luminescent materials relative to the host material is quite small. It is difficult to control co-evaporation and the composition of the luminescent materials may be changed that cause worse reproducibility and low yields. While making the white light OLED with two-wavelength or multiple wavelengths, it is more difficult to control the doping of two or multiple luminescent materials and the host material that cause practical obstacles.

The white light OLED device is further made by pre-dissolving the organic luminescent material and the host material in prior arts. The manufacture way is that various luminescent materials and the material are directly mixed under powder. After cooling, the mixed material is evaporated by evaporation to make the white light OLED device. The white light OLED device with a single light emitting layer is successfully made by exempting from the co-evaporation fabrication. However, the fabrication of the mixed material needs to be fused and mixed at an environment filled with nitrogen and under high temperatures and high pressures. The process may cause deterioration of the organic luminescent material. In addition, if the organic luminescent material with higher glass transition temperatures (Tg), higher fusing temperatures are needed, thereby causing inconvenience in fabrication. Moreover, thermal chemical reaction may happen to cause deterioration of the organic luminescent material. The production is seriously restricted by the manufacture way.

To overcome the foregoing shortcomings of the prior arts, the inventor of the present invention based on years of experience on related research and development invents an organic light emitting diode device and light emitting layer manufacture method thereof to overcome the foregoing shortcomings.

### SUMMARY OF THE INVENTION

Accordingly, an object of the present invention is to provide an organic light emitting diode device and light emitting layer manufacture method thereof. More specifically, an organic solvent is used to manufacture the light emitting layer of the organic light emitting diode device.

In order to achieve the foregoing object, the method for manufacturing the light emitting layer of the organic light emitting diode device disclosed by the present invention comprises the steps of: Provided an organic solvent as Toluene, Acetone or Tetrahydrofuran (THF) to dissolve each luminescent material and each host material respectively; mixed a solution of the luminescent material and a solution of the host material based on a predetermined material concentration to produce a mixed solution; dried the mixed solution through a drying procedure to produce a solid mixed material; lastly, fabricated the solid mixed material to make a light emitting layer through a vapor deposition.

In accordance with the manufacture method for manufacturing the light emitting layer of the organic light emitting diode device uses the organic solvent to simplify the restrictions for the light emitting layer of the OLED device. Simultaneously, multi-source synchronization of co-evaporation can be avoided. Single source evaporation is merely used to finish the required light emitting layer. It is not difficult to control the concentration and fill with nitrogen under high temperatures and high pressures so as to have high reproducibility. The luminescence efficiency is then improved to increase the convenience in industry productions.

Other features and advantages of the present invention and variations thereof will become apparent from the following description, drawings, and claims.

### BRIEF DESCRIPTION OF THE DRAWINGS

FIG. 1 is a cross-sectional drawing illustrating a conventional organic light emitting diode (OLED) device;

FIG. 2 is a schematic diagram illustrating a color coordinate showed by two-dimensional pattern of a CIE coordinate;

FIG. 3 is a flowchart illustrating a manufacture method for manufacturing a light emitting layer of an OLED device of the present invention;

FIG. 4 is a cross-sectional drawing illustrating an OLED device according to a preferred embodiment of the present invention;

FIG. 5 is a cross-sectional drawing illustrating an OLED device according to a preferred embodiment of the present invention;

FIG. 6 is a cross-sectional drawing illustrating an OLED device according to a preferred embodiment of the present invention;

FIG. 7 is a cross-sectional drawing illustrating an OLED device according to a preferred embodiment of the present invention;

FIG. 8 is cross-sectional drawing illustrating an OLED device according to a preferred embodiment of the present invention;

FIG. 9 is a table illustrating a luminescent material mixing concentration of an OLED device with multiple wavelengths of the present invention;

FIG. 10 is an electroluminescence spectrogram illustrating imposed to the white OLED device of number 3 according to FIG. 9;

FIG. 11 is a diagram illustrating the changes of a CIE color coordinate of numbers 1˜7 according FIG. 9;

FIG. 12 is a diagram illustrating the changes of a CIE color coordinate of numbers 8˜11 according to FIG. 9; and

FIG. 13 is a cross-sectional drawing illustrating a phosphorescent OLED device according to a preferred embodiment of the present invention.

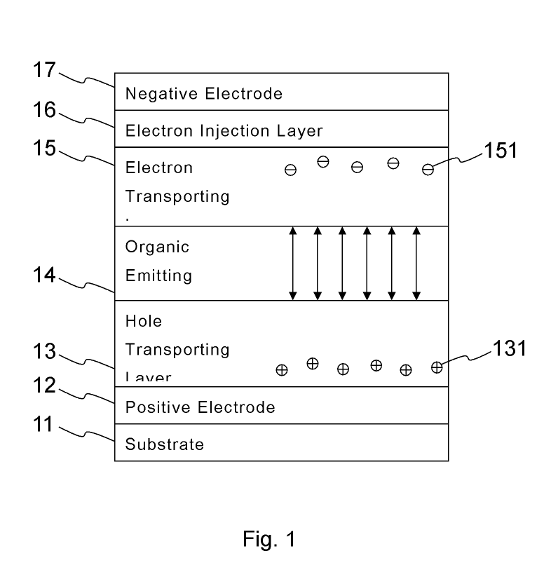

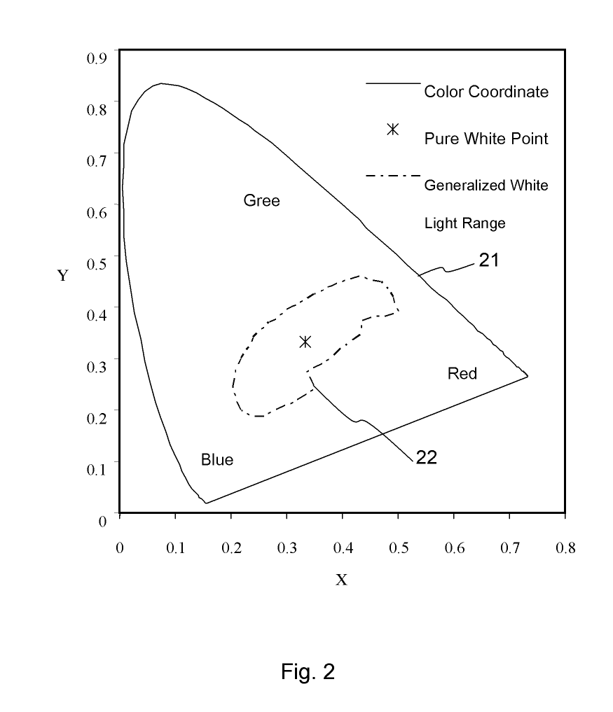

### DETAILED DESCRIPTION OF THE PREFERRED EMBODIMENTS

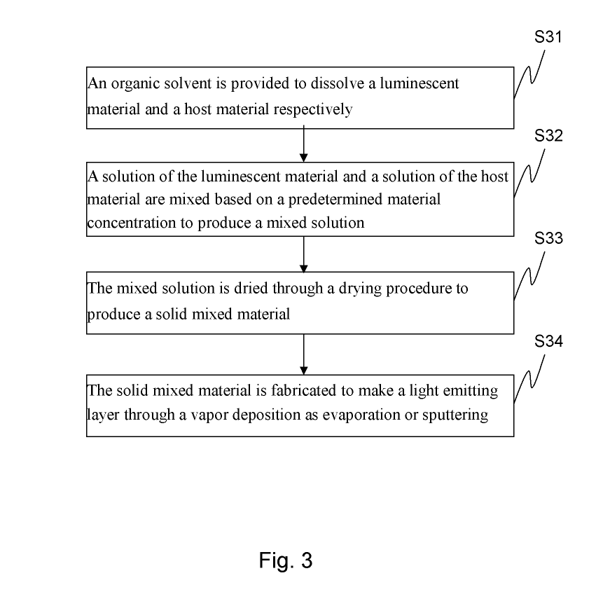

Referring to FIG. 3, a flowchart illustrates a manufacture method for manufacturing a light emitting layer of an organic light emitting diode (OLED) device of the present invention. The method comprises the following steps:

Step S31: An organic solvent is provided to dissolve a luminescent material and a host material respectively;

Step S32: A solution of the luminescent material and a solution of the host material are mixed based on a predetermined material concentration to produce a mixed solution;

Step S33: The mixed solution is dried through a drying procedure to produce a solid mixed material; and

Step S34: The solid mixed material is fabricated to make a light emitting layer through a vapor deposition as evaporation or sputtering. Toluene, Acetone or Tetrahydrofuran (THF) is taken to be the organic solvent. A fluorescent material or a phosphorescent material is taken to be the luminescent material. The host material which is mixed with the fluorescent material is preferably a single or various binding organic materials from α-NPD, spiro-NPD, NPB, spiro-NPB, TPD, spiro-TPD, TBADN, MADN, ZnBOX, AND, TDAF, P-DMDPVBi, BDAF, TSBF, BSBF, TCP, BAlq, BPhen, PBD, SAlq, DPA, TTBND, PDD, TAZ, spiro-TAD, Bebq2, BePP2, BNA, Alq₃, DPVBi, BANE, Rubrene or CBP. The binding energy gap of the organic materials is greater than the fluorescent material. The host material which is mixed with the phosphorescent material is preferably a single or various binding materials from spiro-CBP, UGH2, CBP, mCP, CDBP, TPBi, TCTA or BCP. The binding energy gap of the organic materials is greater than the phosphorescent material. The purpose is to allow the luminescence spectrum emitted by the light emitting layer to cover an ultraviolet light from an infrared light. A single or various bindings from an electron transporting material, an electron injection material, a hole-transporting material, a hole-injection material, a hole-blocking material or a functional supporting material are doped into the host material to allow the light emitting layer to have functionality. In addition, the color light emitted by the light emitting layer uses CIE color coordinate to mark x coordinate range between 0.25 and 0.45 and y coordinate range between 0.25 and 0.45. The light emitting layer emits the light with color rendering index of above 70.

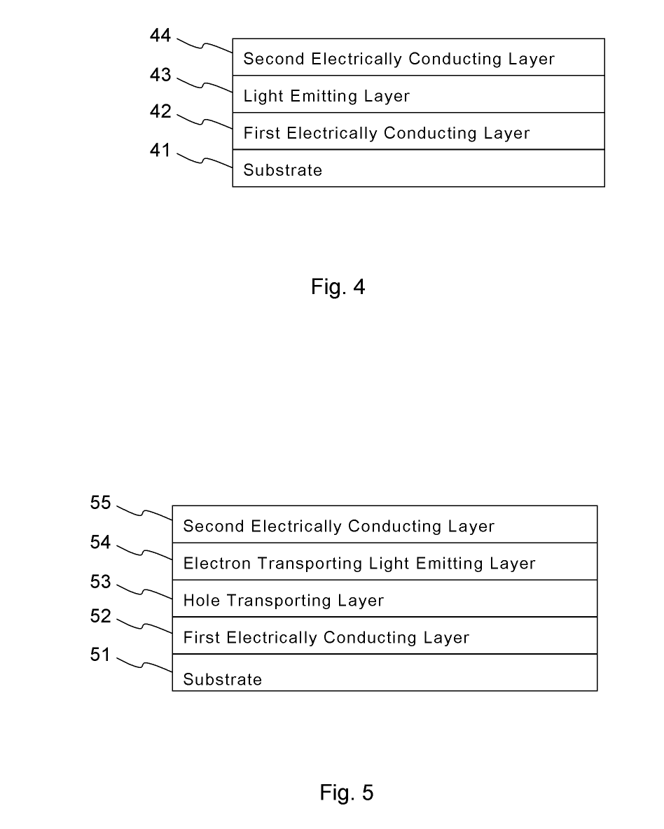

Referring to FIG. 4, a cross-sectional drawing illustrates an OLED device according to a preferred embodiment of the present invention. The structure of the OLED device comprises a substrate 41, a first electrically conducting layer 42, a light emitting layer 43 and a second electrically conducting layer 44. The first electrically conducting layer 42 is disposed on the substrate 41. The light emitting layer 43 is disposed on the first electrically conducting layer 42. The second electrically conducting layer 44 is disposed on the light emitting layer 43. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the light emitting layer 43 through a vapor deposition as evaporation or sputtering. The manufacture process for manufacturing the OLED device is: The substrate 41 of the first electrically conducting layer 42 with Indium tin oxide (ITO) as an ITO glass is washed by ultrasonic agitation by sequentially using detergent, deionized water, acetone and isopropyl alcohol. The ITO glass is then put in hydrogen peroxide with boiling to perform a surface processing. After the surface of the ITO glass is then dried by nitrogen, the ITO glass is put in a vacuum cavity. Under the vacuum pressure of 10⁻⁵ Torr, the light emitting layer 43 with 60 nm (nanometer) and the second electrically conduction layer 44 with 150 nm aluminum electrode are sequentially deposited by thermal evaporation or sputtering on the first electrically conduction layer 42.

The light emitting layer 43 is that a luminescent material with 0.1 mg (milligram) green C545T and a host material with 10 mg Alq₃ are dissolved in an organic solvent such as toluene, acetone or THF respectively. The required C545T luminescent material is formed a mixed solution with 1% C545T luminescent material based on a predetermined material concentration. The mixed solution is put in a vacuum dryer for drying with 80° C. (centigrade) to remove the organic solvent. The mixed solution is then dried to form a solid mixed material. The solid mixed material is a target of the green light emitting layer. The solid mixed material is fabricated by using vapor deposition as evaporation or sputtering to form a thin film of the light emitting layer 43. The maximum efficiency of energy conversion is 1.31 m/W and the maximum brightness is 3,500 cd/m² by measuring the OLED device of the green light emitting layer.

Referring to FIG. 5, a cross-sectional drawing illustrates an OLED device according to a preferred embodiment of the preset invention. The structure of the OLED device comprises a substrate 51, a first electrically conducting layer 52, a hole-transporting layer 53, an electron transporting light emitting layer 54 and a second electrically conducting layer 55. The first electrically conducting layer 52 is disposed on the substrate 51. The hole-transporting layer 53 is disposed on the first electrically conducting layer 52. The electron transporting light emitting layer 54 is disposed on the hole-transporting layer 53. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the electron transporting light emitting layer 54 through a vapor deposition as evaporation or sputtering. The manufacture process for manufacturing the OLED device is: The substrate 51 of the first electrically conducting layer 52 with Indium tin oxide (ITO) as an ITO glass is washed by ultrasonic agitation by sequentially using detergent, deionized water, acetone and isopropyl alcohol. The ITO glass is then put in hydrogen peroxide with boiling to perform a surface processing. After the surface of the ITO glass is then dried by nitrogen, the ITO glass is put in a vacuum cavity. Under the vacuum pressure of 10⁻⁵ Torr, the NPB hole-transporting layer 53 with 45 nm, the electron transporting light emitting layer 54 with 50 nm and the second electrically conduction layer 55 with 150 nm aluminum electrode are sequentially deposited by thermal evaporation or sputtering on the first electrically conduction layer 52.

Simultaneously, the manufacture process for manufacturing the electron transporting light emitting layer 54 is the same as the foregoing light emitting layer that 1% C545T green luminescent material is doped in a solid mixed material. The maximum efficiency of energy conversion is 2.51 m/W and the maximum brightness is 8350 cd/m² by measuring the OLED device of the green electron transporting light emitting layer.

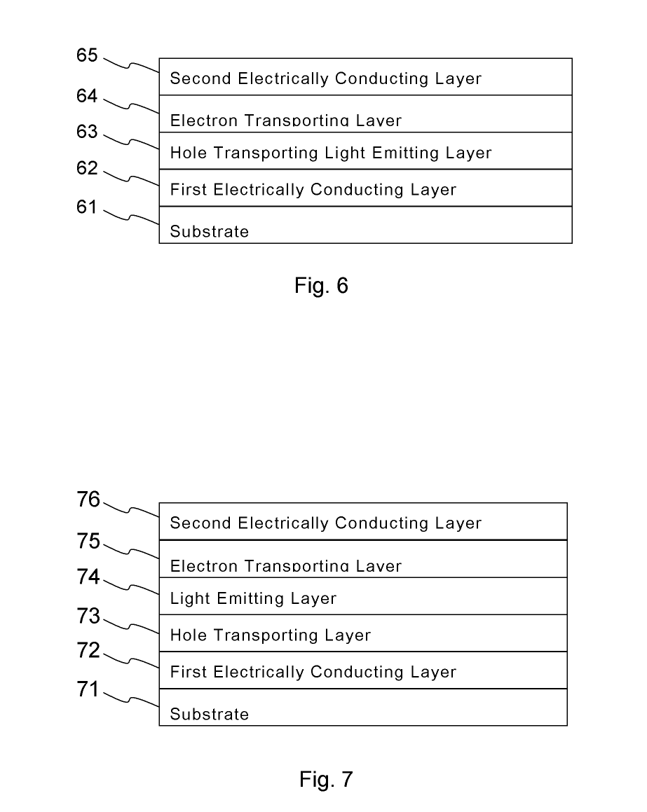

Referring to FIG. 6, a cross-sectional drawing illustrates an OLED device according to a preferred embodiment of the present invention. The OLED device sequentially comprises a substrate 61, a first electrically conducting layer 62, a hole-transporting light emitting layer 63, an electron transporting layer 64 and a second electrically conducting layer 65. The first electrically conducting layer 62 is disposed on the substrate 61. The hole-transporting light emitting layer 63 is disposed on the first electrically conducting layer 62. The electron transporting layer 64 is disposed on the hole-transporting light emitting layer 63. The second electrically conducting layer 65 is disposed on the electron transporting layer 64. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the hole-transporting light emitting layer 63 through a vapor deposition as evaporation or sputtering.

Referring to FIG. 7, a cross-sectional drawing illustrates an OLED device according to a preferred embodiment of the present invention. The structure of the OLED device sequentially comprises a substrate 71, a first electrically conducting layer 72, a hole-transporting layer 73, a light emitting layer 74, an electron transporting layer 75 and a second electrically conducting layer 76. The first electrically conducting layer 72 is disposed on the substrate 71. The hole-transporting layer 73 is disposed on the first electrically conducting layer 72. The light emitting layer 74 is disposed on the hole-transporting layer 73. The electron transporting layer 75 is disposed on the light emitting layer 74. The second electrically conducting layer 76 is disposed on the electron transporting layer 75. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the light emitting layer 74 through a vapor deposition as evaporation or sputtering. In FIG. 4, FIG. 5, FIG. 6 and FIG. 7, toluene, acetone or tetrahydrofuran (THF) is taken to be the organic solvent. A fluorescent material or a phosphorescent material is taken to be the luminescent material. The host material which is mixed with the fluorescent material is preferably a single or various binding organic materials from α-NPD, spiro-NPD, NPB, spiro-NPB, TPD, spiro-TPD, TBADN, MADN, ZnBOX, AND, TDAF, P-DMDPVBi, BDAF, TSBF, BSBF, TCP, BAlq, BPhen, PBD, SAlq, DPA, TTBND, PDD, TAZ, spiro-TAD, Bebq2, BePP2, BNA, Alq₃, DPVBi, BANE, Rubrene or CBP. The binding energy gap of the organic materials is greater than the fluorescent material. The host material which is mixed with the phosphorescent material is preferably a single or various binding materials from spiro-CBP, UGH2, CBP, mCP, CDBP, TPBi, TCTA or BCP. The binding energy gap of the organic materials is greater than the phosphorescent material. The purpose is to allow the luminescence spectrum emitted by the light emitting layer to cover an ultraviolet light from an infrared light. A single or various bindings from an electron transporting material, an electron injection material, a hole-transporting material, a hole-injection material, a hole-blocking material or a functional supporting material are doped into the host material to allow the light emitting layer to have functionality. Simultaneously, at least one functional supporting layer is further formed between each layer of the OLED device. In addition, the color light emitted by the light emitting layer uses CIE color coordinate to mark x coordinate range between 0.25 and 0.45 and y coordinate range between 0.25 and 0.45. The light emitting layer emits the light with color rendering index of above 70.

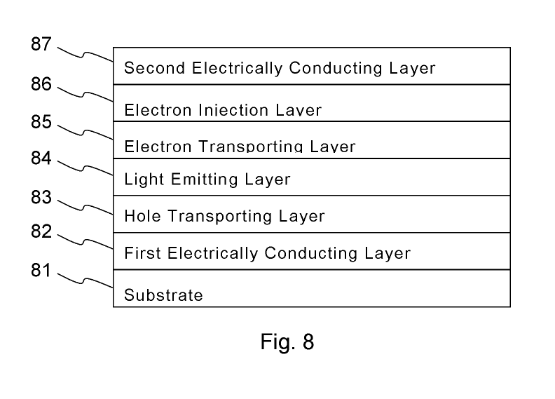

Referring to FIG. 8, a cross-sectional drawing illustrates an OLED device according to a preferred embodiment of the present invention. The structure of the OLED device sequentially comprises a substrate 81, a first electrically conducting layer 82, a hole-transporting layer 83, a light emitting layer 84, an electron transporting layer 85, an electron injection layer 86 and a second electrically conducting layer 87. The first electrically conducting layer 82 is disposed on the substrate 81. The hole-transporting layer 83 is disposed on the first electrically conducting layer 82. The light emitting layer 84 is disposed on the hole-transporting layer 83. The electron transporting layer 85 is disposed on the light emitting layer 84. The electron injection layer 86 is disposed on the electron transporting layer 85. The second electrically conducting layer 87 is disposed on the electron injection layer 86. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the light emitting layer 84 through a vapor deposition as evaporation or sputtering. The manufacture process for manufacturing the OLED device is: The substrate 81 of the first electrically conducting layer 82 with Indium tin oxide (ITO) as an ITO glass is washed by ultrasonic agitation by sequentially using detergent, deionized water, acetone and isopropyl alcohol. The ITO glass is then put in hydrogen peroxide with boiling to perform a surface processing. After the surface of the ITO glass is then dried by nitrogen, the ITO glass is put in a vacuum cavity Under the vacuum pressure of 10⁻⁵ Torr, the NPB hole-transporting layer 83 with 40 nm, the light emitting layer 84 with 30 nm, the TPBi electron transporting layer 85 with 40 nm, the LiF electron injection layer 86 with 0.5 nm and the second electrically conduction layer 87 with 150 nm aluminum electrode are sequentially deposited by thermal evaporation or sputtering on the first electrically conduction layer 82.

Simultaneously, the manufacture process for manufacturing the light emitting layer 84 is the same as the foregoing light emitting layer as shown in FIG. 4 that a 2% DCM2 red luminescent material is doped into a solid mixed material. The maximum efficiency of energy conversion is 0.6 m/W and the maximum brightness is 3000 cd/m² by measuring the OLED device of the red light emitting layer. The CIE color coordinate is (0.65, 0.35).

Moreover, the light emitting layer 84 is a solid mixed material doped with a 1% C545T green luminescent material. The maximum efficiency of energy conversion is 9.9 m/W and the maximum brightness is 41500 cd/m² by measuring the OLED device of the green light emitting layer. The CIE color coordinate is (0.33, 0.64).

Furthermore, the light emitting layer 84 is a solid mixed material doped with a DPVBi blue host material and a 2% DSA blue luminescent material. The maximum efficiency of energy conversion is 1.9 m/W and the maximum brightness is 7000 cd/m² by measuring the OLED device of the blue light emitting layer. The CIE color coordinate is (0.16, 0.16).

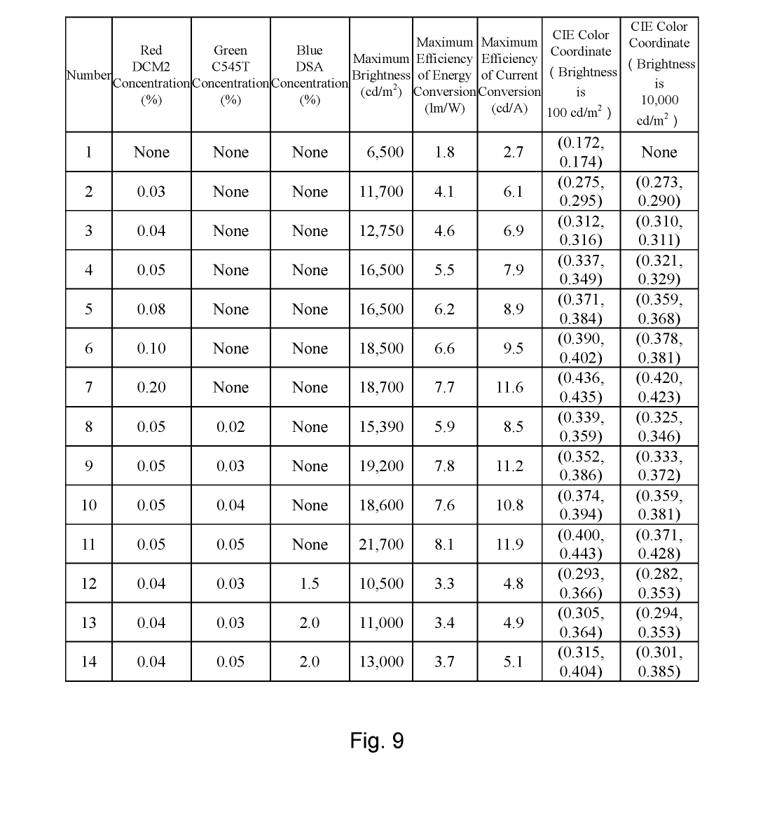

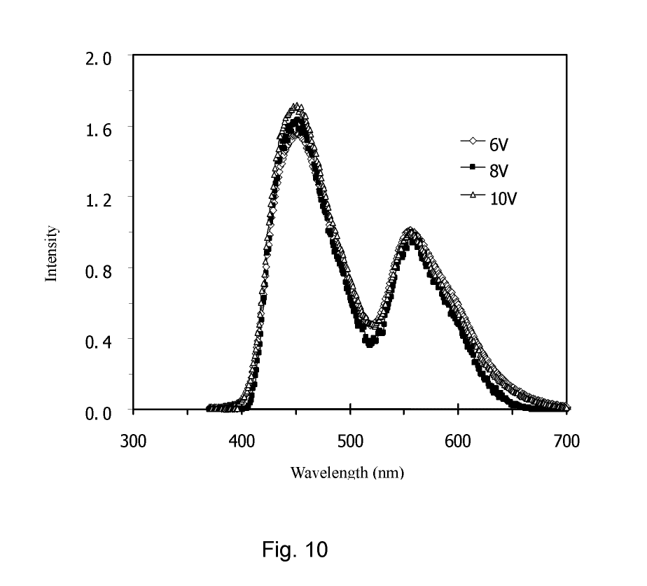

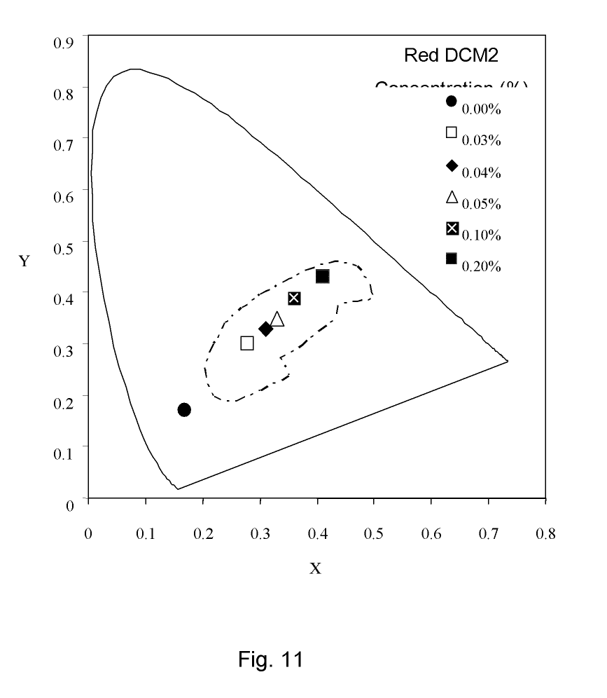

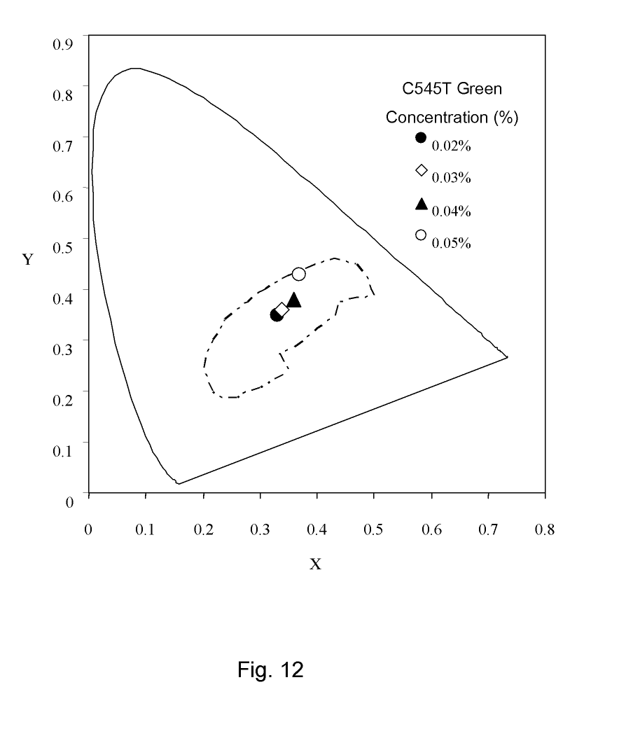

The light emitting layer 84 can have mixed materials with multiple wavelengths to make an OLED device which emits a white light. Referring to FIG. 9, a table illustrates a luminescent material mixing concentration of an OLED device with multiple wavelengths of the present invention. Number 1 is a reference blue OLED device. Numbers 2 to 14 are a white OLED device. Referring to FIG. 10, an electroluminescence spectrogram illustrates voltages imposed to the white OLED device of number 3 according to FIG. 9. When the voltages are increased to 10V from 6V, the spectrum does not have obvious changes. The white OLED device only has a single light emitting layer. The color shift generated by the position changes of recombination area of charge carriers is effectively improved when voltages are imposed or current is changed. The present invention uses organic solvents to uniformly mix various organic materials to allow the luminescent material to be uniformly spread in the host material. Non-uniform color light caused by non-uniform distribution of molecules is then reduced. Referring to FIG. 11 and FIG. 12, FIG. 11 is a diagram illustrating the changes of a CIE color coordinate of numbers 17 according FIG. 9. FIG. 12 is a diagram illustrating the changes of a CIE color coordinate of numbers 8˜11 according to FIG. 9. The CIE color coordinate of the OLED device made by the mixing concentration of other luminescent materials locates at a generalized white light range except that the concentration of number 1 is the blue OLED device of 0.00%.

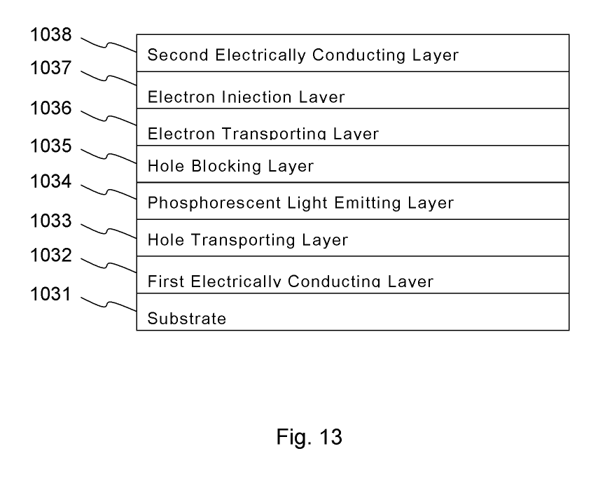

Referring to FIG. 13, a cross-sectional drawing illustrates an OLED device according to a preferred embodiment of the present invention. The structure of the OLED device sequentially comprises a substrate 1031, a first electrically conducting layer 1032, a hole-transporting layer 1033, a phosphorescent light emitting layer 1034, a hole-blocking layer 1035, an electron transporting layer 1036, an electron injection layer 1037 and a second electrically conducting layer 1038. The first electrically conducting layer 1032 is disposed on the substrate 1031. The hole-transporting layer 1033 is disposed on the first electrically conducting layer 1032. The phosphorescent light emitting layer 1034 is disposed on the hole-transporting layer 1033. The hole-blocking layer 1035 is disposed on the phosphorescent light emitting layer 1034. The electron transporting layer 1036 is disposed on the hole-blocking layer 1035. The electron injection layer 1037 is disposed on the electron transporting layer 1036. The second electrically conducting layer 1038 is disposed on the electron injection layer 1037. The luminescent material and the host material are dissolved respectively through an organic solvent. A solution of the luminescent material and a solution of the host material are mixed based on a predetermined material concentration to produce a mixed solution. The mixed solution is then dried by a drying procedure to produce a solid mixed material. The solid mixed material is fabricated to form the phosphorescent light emitting layer 1034 through a vapor deposition as evaporation or sputtering. The manufacture process for manufacturing the OLED device is: The substrate 1031 of the first electrically conducting layer 1032 with Indium tin oxide (ITO) as an ITO glass is washed by ultrasonic agitation by sequentially using detergent, deionized water, acetone and isopropyl alcohol. The ITO glass is then put in hydrogen peroxide with boiling to perform a surface processing. After the surface of the ITO glass is then dried by nitrogen, the ITO glass is put in a vacuum cavity. Under the vacuum pressure of 10⁻⁵ Torr, the NPB hole-transporting layer 1033 with 45 nm, the phosphorescent light emitting layer 1034 with 30 nm, the hole-blocking layer 1035 with 10 nm, the Alq₃ electron transporting layer 1036 with 40 nm, the LiF electron injection layer 1037 with 0.5 nm and the second electrically conduction layer 1038 with 150 nm aluminum electrode are sequentially deposited by thermal evaporation or sputtering on the first electrically conduction layer 1032.

Simultaneously, the manufacture process for manufacturing the phosphorescent light emitting layer 1034 is the same as the foregoing light emitting layer as shown in FIG. 4 that is a solid mixed material doped with the 7% Ir (DBQ)₂acac red phosphorescent luminescent material and the CBP host material. The maximum efficiency of energy conversion is 7.0 m/W and the maximum brightness is 26500 cd/m² by measuring the red phosphorescent OLED device. The CIE color coordinate is (0.61, 0.39).

Furthermore, the phosphorescent light emitting layer 1034 is a solid mixed material doped with a 8% Ir (ppy)₃ green phosphorescent luminescent material and a CBP host material. The maximum efficiency of energy conversion is 16 m/W and the maximum brightness is 42000 cd/m² by measuring the green phosphorescent OLED device. The CIE color coordinate is (0.32, 0.60).

Moreover, the phosphorescent light emitting layer 1034 is a solid mixed material doped with a 6% Firpic blue phosphorescent luminescent material and CBP, mCP and TCTA host material. The maximum efficiency of energy conversion is 5 m/W, 6.8 m/W and 2.1 m/w respectively, and the maximum brightness is 9000 cd/m², 23500 cd/m² and 8300 cd/m² respectively by measuring the blue phosphorescent OLED device. The CIE color coordinate is (0.22, 0.36), (0.20, 0.37) and (0.20, 0.34) respectively.

Furthermore, the phosphorescent light emitting layer 1034 is to pre-dissolve the red phosphorescent luminescent material Ir(DBQ)₂acac, the green phosphorescent luminescent material Ir(ppy)₃, the blue phosphorescent luminescent material Flpic and the host material in advance by using organic solvents. The three phosphorescent luminescent materials are then mixed based on individual required concentration. A mixed material which is dried is then formed to produce a white light emitting layer by using evaporation or sputtering. A white phosphorescent OLED device is then made.

The phosphorescent light emitting layer 1034 can mix a fluorescent material such as the red phosphorescent luminescent material Ir (DBQ)₂acac, the green phosphorescent luminescent material Ir(ppy)₃, the blue fluorescent material DSA and the host material. By using organic solvents, various materials are pre-dissolved to be mixed based on individual required concentration. A mixed material which is dried is fabricated to produce a white light emitting layer by using evaporation or sputtering so as to make a white OLED device that effectively combines the fluorescent luminescent material and the phosphorescent luminescent material into a host material. The white light is then mixed by emitting lights simultaneously

The binding of the luminescent materials also comprises the fluorescent luminescent material and the phosphorescent luminescent material simultaneously to allow the spectrum emitted by the light emitting layer to cover an ultraviolet light from an infrared light. The host material is also a single or various binding organic materials from α-NPD, spiro-NPD, NPB, spiro-NPB, TPD, spiro-TPD, TBADN, MADN, ZnBOX, AND, TDAF, P-DMDPVBi, BDAF, TSBF, BSBF, TCP, BAlq, BPhen, PBD, SAlq, DPA, TTBND, PDD, TAZ, spiro-TAD, Bebq2, BePP2, BNA, Alq₃, DPVBi, BANE, Rubrene, spiro-CBP, UGH2, CBP, mCP, CDBP, TPBi, TCTA or CBP. The binding energy gap of the organic material is greater than the fluorescent luminescent material and the phosphorescent material.

The OLED device made by the light emitting layer manufacture method of the present invention can select various luminescent materials with different luminescence spectrums and various host materials simultaneously. There is no need to be restricted by more carrier equipment while in the vacuum evaporation fabrication. Each luminescent material can be easily and precisely controlled to achieve required concentrations at will and has high reproducibility. In addition, the method of the present invention is also applied in the OLED device with varied structures.

Although the features and advantages of the embodiments according to the preferred invention are disclosed, it is not limited to the embodiments described above, but encompasses any and all modifications and changes within the spirit and scope of the following claims.

What is claimed is:

1. A method for manufacturing a light emitting layer of an organic light emitting diode, comprising:
providing an organic solvent for dissolving at least one luminescent material and at least one host material respectively;
mixing a solution of the luminescent material and a solution of the host material based on a predetermined material concentration to produce a mixed solution;
drying the mixed solution to produce a solid mixed material through a drying procedure; and
fabricating the solid mixed material to make a light emitting layer through a vapor deposition.

2. The method of claim 1, further comprising the step of providing toluene to be the organic solvent.

3. The method of claim 1, further comprising the step of providing acetone to be the organic solvent.

4. The method of claim 1, further comprising the step of providing terahydrofuran (THF) to be the organic solvent.

5. The method of claim 1, further comprising the step of providing a fluorescent material to be the luminescent material in order to allow the luminescence spectrum emitted by the light emitting layer to cover an ultraviolet light from an infrared light.

6. The method of claim 5, further comprising the step of providing a single or various binding organic materials from Alq₃, DPVBi, BANE, Rubrene or CBP to be the host material, the host material being mixed with the fluorescent material.

7. The method of claim 1, further comprising the step of providing a phosphorescent material to be the luminescent material in order to allow the luminescence spectrum emitted by the light emitting layer to cover an ultraviolet light from an infrared light.

8. The method of claim 1, further comprising providing a single or various binding organic materials from CBP, mCP, CDBP, TPBi, TCTA or BCP to be the host material, the host material being mixed with the phosphorescent material.

9. The method of claim 1, further comprising the step of providing a fluorescent material and a phosphorescent material to be the luminescent material in order to allow the luminescence spectrum emitted by the light emitting layer to cover an ultraviolet light from an infrared light.

10. The method of claim 1, further comprising the step of providing a single or various binding organic materials from Alq₃, DPVBi, BANE, Rubrene, CBP, mCP, CDBP, TPBi, TCTA or BCP to be the host material.

11. The method of claim 1, further comprising the step of providing a single or various binding from an electron-transporting material, an electron injection material, a hole-transporting material, a hole injection material, a hole blocking material or a functional supporting material to be doped into the host material so as to allow the light emitting layer to have functionality.

12. The method of claim 1, further comprising the step of using a Commission International deL'Eclairage (CIE) color coordinate for the color light emitted by the light emitting layer to mark x coordinate range between 0.25 to 0.45 and y coordinate range between 0.25 to 0.45.

13. The method of claim 1, wherein the light emitting layer emits the light with color rendering index of above 70.

14. The method of claim 1, further comprising the step of providing evaporation to be the vapor deposition.

15. The method of claim 1, further comprising the step of providing a sputtering to be the vapor deposition.

16. An organic light emitting diode device comprising:
a substrate;
a first electrically conducting layer disposed on the substrate;
a light emitting layer disposed on the first electrically conducting layer; and
a second electrically conducting layer disposed on the light emitting layer;
wherein at least one luminescent material and at least one host material are dissolved respectively through an organic solvent, and a solution of the luminescent material and a solution of the host material are mixed based on a predetermined material concentration to produce a mixed solution, and the mixed solution is dried by a drying procedure to produce a solid mixed material, and the solid mixed material is fabricated to form the light emitting layer through a vapor deposition.

17. The organic light emitting diode device of claim 16, wherein the organic solvent is Toluene.

18. The organic light emitting diode device of claim 16, wherein the organic solvent is Acetone.

19. The organic light emitting diode device of claim 16, wherein the organic solvent is THF.

20. The organic light emitting diode device of claim 16, wherein the luminescent material is a fluorescent material to allow the luminescence spectrum emitted by the light emitting layer to cover an ultraviolet light from an infrared light.

21. The organic light emitting diode device of claim 16, wherein the host material is a single or various binding organic materials from Alq₃, DPVBi, BANE, Rubrene or CBP, and the host material is mixed with the fluorescent material.

22. The organic light emitting diode device of claim 16, wherein the luminescent material is a phosphorescent material to allow the luminescence spectrum emitted by the light emitting layer to cover an ultraviolet light from an infrared light.

23. The organic light emitting diode device of claim 22, wherein the host material is a single or various binding organic materials from CBP, mCP, CDBP, TPBi, TCTA or BCP, and the host material is mixed with the phosphorescent material.

24. The organic light emitting diode device of claim 16, wherein the luminescent material is a fluorescent material and a phosphorescent material to allow the luminescence spectrum emitted by the light emitting layer to cover an ultraviolet light from an infrared light.

25. The organic light emitting diode device of claim 16, wherein the host material is a single or various binding organic materials from Alq₃, DPVBi, BANE, Rubrene, CBP, mCP, CDBP, TPBi, TCTA or BCP.

26. The organic light emitting diode device of claim 16, wherein the host material is doped with a single or various binding from an electron-transporting material, an electron injection material, a hole-transporting material, a hole injection material, a hole blocking material or a functional supporting material so as to allow the light emitting layer to have functionality.

27. The organic light emitting diode device of claim 16, wherein at least one functional supporting layer is formed between the first electrically conducting layer and the light emitting layer.

28. The organic light emitting device of claim 16, wherein at least one functional supporting layer is formed between the second electrically conducting layer and the light emitting layer.

29. The organic light emitting diode device of claim 16, wherein the color light emitted by the light emitting layer uses a CIE color coordinate to mark x coordinate range between 0.25 and 0.45 and y coordinate range between 0.25 and 0.45.

30. The organic light emitting diode device of claim 16, wherein the light emitting layer emits the light with color rendering index of above 70.

31. The organic light emitting diode device of claim 16, wherein the vapor deposition is evaporation.

32. The organic light emitting diode device of claim 16, wherein the vapor deposition is sputtering.

33. An organic light emitting diode device comprising:
a substrate;
a first electrically conducting layer disposed on the substrate;
a hole-transporting layer disposed on the first electrically conducting layer;
an electron transporting light emitting layer disposed on the hole-transporting layer; and
a second electrically conducting layer disposed on the electron transporting light emitting layer;
wherein at least one luminescent material and at least one host material are dissolved respectively through an organic solvent, and a solution of the luminescent material and a solution of the host material are mixed based on a predetermined material concentration to produce a mixed solution, and the mixed solution is dried by a drying procedure to produce a solid mixed material, and the solid mixed material is fabricated to form the electron transporting light emitting layer through a vapor deposition.

34. The organic light emitting diode device of claim 33, wherein the organic solvent is Toluene.

35. The organic light emitting diode device of claim 33, wherein the organic solvent is Acetone.

36. The organic light emitting diode device of claim 33, wherein the organic solvent is THF.

37. The organic light emitting diode device of claim 33, wherein the luminescent material is a fluorescent material to allow the luminescence spectrum emitted by the light emitting layer to cover an ultraviolet light from an infrared light.

38. The organic light emitting diode device of claim 33, wherein the host material is a single or various binding organic materials from Alq₃, DPVBi, BANE, Rubrene or CBP, and the host material is mixed with the fluorescent material.

39. The organic light emitting diode device of claim 33, wherein the luminescent material is a phosphorescent material to allow the luminescence spectrum emitted by the light emitting layer to cover an ultraviolet light from an infrared light.

40. The organic light emitting diode device of claim 39, wherein the host material is a single or various binding organic materials from CBP, mCP, CDBP, TPBi, TCTA or BCP, and the host material is mixed with the phosphorescent material.

41. The organic light emitting diode device of claim 33, wherein the luminescent material is a fluorescent material and a phosphorescent material to allow the luminescence spectrum emitted by the light emitting layer to cover an ultraviolet light from an infrared light.

42. The organic light emitting diode device of claim 33, wherein the host material is a single or various binding organic materials from Alq₃, DPVBi, BANE, Rubrene, CBP, mCP, CDBP, TPBi, TCTA or BCP.

43. The organic light emitting diode device of claim 33, wherein the host material is doped with an electron transporting material to fabricate the electron transporting light emitting layer.

44. The organic light emitting diode device of claim 33, wherein at least one functional supporting layer is formed between the first electrically conducting layer and the hole-transporting layer.

45. The organic light emitting diode device of claim 33, wherein at least one functional supporting layer is formed between the hole transporting layer and the electron transporting light emitting layer.

46. The organic light emitting diode device of claim 33, wherein at least one functional supporting layer is formed between the electron transporting light emitting layer and the second electrically conducting layer.

47. The organic light emitting diode device of claim 33, wherein the color light emitted by the electron transporting light emitting layer uses a CIE color coordinate to mark x coordinate range between 0.25 and 0.45 and y coordinate range between 0.25 and 0.45.

48. The organic light emitting diode device of claim 33, wherein the electron transporting light emitting layer emits the light with color rendering index of above 70.

49. The organic light emitting diode device of claim 33, wherein the vapor deposition is evaporation.

50. The organic light emitting diode device of claim 33, wherein the vapor deposition is sputtering.

51. An organic light emitting diode device comprising:
a substrate;
a first electrically conducting layer disposed on the substrate;
a hole-transporting light emitting layer disposed on the first electrically conducting layer;
an electron transporting layer disposed on the hole-transporting light emitting layer; and
a second electrically conducting layer disposed on the electron transporting layer;
wherein at least one luminescent material and at least one host material are dissolved respectively through an organic solvent, and a solution of the luminescent material and a solution of the host material are mixed based on a predetermined material concentration to produce a mixed solution, and the mixed solution is dried by a drying procedure to produce a solid mixed material, and the solid mixed material is fabricated to form the hole-transporting light emitting layer through a vapor deposition.

52. The organic light emitting diode device of claim 51, wherein the organic solvent is Toluene.

53. The organic light emitting diode device of claim 51, wherein the organic solvent is Acetone.

54. The organic light emitting diode device of claim 51, wherein the organic solvent is THF.

55. The organic light emitting diode device of claim 51, wherein the luminescent material is a fluorescent material to allow the luminescence spectrum emitted by the light emitting layer to cover an ultraviolet light from an infrared light.

56. The organic light emitting diode device of claim 55, wherein the host material is a single or various binding organic materials from Alq₃, DPVBi, BANE, Rubrene or CBP, and the host material is mixed with the fluorescent material.

57. The organic light emitting diode device of claim 51, wherein the luminescent material is a phosphorescent material to allow the luminescence spectrum emitted by the light emitting layer to cover an ultraviolet light from an infrared light.

58. The organic light emitting diode device of claim 57, wherein the host material is a single or various binding organic materials from CBP, mCP, CDBP, TPBi, TCTA or BCP, and the host material is mixed with the phosphorescent material.

59. The organic light emitting diode device of claim 51, wherein the luminescent material is a fluorescent material and a phosphorescent material to allow the luminescence spectrum emitted by the light emitting layer to cover an ultraviolet light from an infrared light.

60. The organic light emitting diode device of claim 51, wherein the host material is a single or various binding organic materials from Alq₃, DPVBi, BANE, Rubrene, CBP, mCP, CDBP, TPBi, TCTA or BCP.

61. The organic light emitting diode device of claim 51, wherein the host material is doped with a hole-transporting material to fabricate the hole-transporting light emitting layer.

62. The organic light emitting diode device of claim 51, wherein at least one functional supporting layer is formed between the first electrically conducting layer and the hole-transporting light emitting layer.

63. The organic light emitting diode device of claim 51, wherein at least one functional supporting layer is formed between the hole-transporting light emitting layer and the electron transporting layer.

64. The organic light emitting diode device of claim 51, wherein at least one functional supporting layer is formed between the electron transporting layer and the second electrically conducting layer.

65. The organic light emitting diode device of claim 51, wherein the color light emitted by the hole-transporting light emitting layer uses a CIE color coordinate to mark x coordinate range between 0.25 and 0.45 and y coordinate range between 0.25 and 0.45.

66. The organic light emitting diode device of claim 51, wherein the hole-transporting light emitting layer emits the light with color rendering index of above 70.

67. The organic light emitting diode device of claim 51, wherein the vapor deposition is evaporation.

68. The organic light emitting diode device of claim 51, wherein the vapor deposition is sputtering.

69. An organic light emitting diode device comprising:
a substrate;
a first electrically conducting layer disposed on the substrate;
a hole-transporting layer disposed on the first electronically conducting layer;
a light emitting layer disposed on the hole-transporting layer;
an electron transporting layer disposed on the light emitting layer; and
a second electrically conducting layer disposed on the electron transporting layer;
wherein at least one luminescent material and at least one host material are dissolved respectively through an organic solvent, and a solution of the luminescent material and a solution of the host material are mixed based on a predetermined material concentration to produce a mixed solution, and the mixed solution is dried by a drying procedure to produce a solid mixed material, and the solid mixed material is fabricated to form the light emitting layer through a vapor deposition.

70. The organic light emitting diode device of claim 69, wherein the organic solvent is Toluene.

71. The organic light emitting diode device of claim 69, wherein the organic solvent is Acetone.

72. The organic light emitting diode device of claim 69, wherein the organic solvent is THF.

73. The organic light emitting diode device of claim 69, wherein the luminescent material is a fluorescent material to allow the luminescence spectrum emitted by the light emitting layer to cover an ultraviolet light from an infrared light.

74. The organic light emitting diode device of claim 73, wherein the host material is a single or various binding organic materials from Alq₃, DPVBi, BANE, Rubrene or CBP, and the host material is mixed with the fluorescent material.

75. The organic light emitting diode device of claim 69, wherein the luminescent material is a phosphorescent material to allow the luminescence spectrum emitted by the light emitting layer to cover an ultraviolet light from an infrared light.

76. The organic light emitting diode device of claim 75, wherein the host material is a single or various binding organic materials from CBP, mCP, CDBP, TPBi, TCTA or BCP, and the host material is mixed with the phosphorescent material.

77. The organic light emitting diode device of claim 69, wherein the luminescent material is a fluorescent material and a phosphorescent material to allow the luminescence spectrum emitted by the light emitting layer to cover an ultraviolet light from an infrared light.

78. The organic light emitting diode device of claim 69, wherein the host material is a single or various binding organic materials from Alq₃, DPVBi, BANE, Rubrene, CBP, mCP, CDBP, TPBi, TCTA or BCP.

79. The organic light emitting diode device of claim 69, wherein the host material is doped with a single or various binding from an electron-transporting material, an electron injection material, a hole-transporting material, a hole injection material, a hole blocking material or a functional supporting material to allow the light emitting layer to have functionality.

80. The organic light emitting diode device of claim 69, wherein at least one functional supporting layer is formed between the first electrically conducting layer and the hole-transporting light emitting layer.

81. The organic light emitting diode device of claim 69, wherein at least one functional supporting layer is formed between the hole-transporting light emitting layer and the light emitting layer.

82. The organic light emitting diode device of claim 69, wherein at least one functional supporting layer is formed between the electron transporting layer and the light emitting layer.

83. The organic light emitting diode device of claim 69, wherein at least one functional supporting layer is formed between the electron transporting layer and the second electrically conducting layer.

84. The organic light emitting diode device of claim 69, wherein the color light emitted by the light emitting layer uses a CIE color coordinate to mark x coordinate range between 0.25 and 0.45 and y coordinate range between 0.25 and 0.45.

85. The organic light emitting diode device of claim 69, wherein the light emitting layer emits the light with color rendering index of above 70.

86. The organic light emitting diode device of claim 69, wherein the vapor deposition is evaporation.

87. The organic light emitting diode device of claim 69, wherein the vapor deposition is sputtering.
